(19) United States
(12) Patent Application Publication
(10) Pub. No.: US 2002/0050828 A1
(43) Pub. Date: May 2, 2002

(54) Multi-feed microwave reflective resonant sensors

(75) Inventors: DeWitt C. Seward IV, Natick, MA (US); John LaChapelle, Princeton, MA (US); D. Clint Seward III, Acton, MA (US)

Correspondence Address: Bowditch & Dewey, LLP, 161 Worcester Road, Framingham, MA, 01701-9320, US

(73) Assignee: General Dielectric, Inc., Acton, MA

(21) Appl. No.: 09/834,040

(22) Filed: Apr. 12, 2001

Related U.S. Application Data
(60) Provisional application No. 60/197,527, filed on Apr. 14, 2000.

(51) Int. Cl. G01R 27/28

(52) U.S. Cl. 324/652

(57) ABSTRACT

Methods techniques have been developed for making dielectric measurements of materials in the near field of microwave antennas. These techniques overcome the limitations of previous devices as the size, shape, orientation, and location of a sample can have a substantial impact on dielectric measurements.

### RELATED APPLICATIONS

This application claims the benefit of U.S. Provisional Application No. 60/197,527, filed on Apr. 14, 2000. The entire teachings of the above application is incorporated herein by reference.

### BACKGROUND OF THE INVENTION

There is a need for making dielectric measurements for security, for laboratory, for industrial, and other applications. For security applications, the ability to make dielectric measurements of samples can allow the user to verify the contents of a container by verifying the dielectric constant of the material inside. For example, if the wine in a wine bottle were to be replaced with a hazardous liquid or explosive, existing detection systems could not detect the hazardous material.

In the laboratory, restrictions on sample characteristics can adversely affect the dielectric measurement process. It can effectively restrict which materials can be tested. For example, if a material is difficult to obtain or to manufacture, restrictions on the size of the material can make it difficult to use the measurement technique. For the case of non-isotropic dielectric materials, the orientation of the dielectric material can have a major impact on sensor readings.

There is a class of microwave reflective resonant sensors that can take dielectric measurements by using a single antenna to interrogate samples with a swept frequency microwave source. The material is placed in the near field of the antenna, within approximately 2.5λ from the antenna aperture. A single port dielectric resonant sensor, for example, uses a swept frequency source to measure the dielectric properties of a material under test. This technique requires precise sample dimensions in order to make its measurements, and is therefore incompatible with most real world situations.

An in situ sensor that was a linearly polarized, highly resonant, microstrip antenna with a swept frequency microwave source has been described for the purpose of making very precise dielectric measurements. This system required a single feed, linearly polarized antenna in order to achieve a high coupling factor with the material under test. The orientation of the material under test relative to the antenna is also critical to device operation. Further, the material must be in direct contact with the antenna in order to achieve the high coupling factor. This system was incompatible with measuring materials in an arbitrary container as mentioned before. Each antenna would need to be tuned to the specific container shape and material, a requirement that is impractical at best and, for the case of those attempting to conceal a dangerous substance, usually impossible. A high coupling factor is required for making accurate measurements of the complex dielectric constant (ε*=ε′+jε″), as well as an accurate measurement of the material conductivity (σ). However, the technique is of limited use if the antenna or an intermediary dielectric are not in full contact with the material. Further, the material in test needs to be electrically infinite with respect to the resonant antenna in order for the technique to be accurate.

While both of these techniques are very useful in certain situations, they impose restrictions that limit applicability. Thus, further improvements are needed.

### SUMMARY OF THE INVENTION

The present invention uses a series of techniques that increase the robustness of the dielectric measurements made from a microstrip resonant sensor. The instrument includes swept frequency microwave source to measure the resonant frequency of the resonator.

The first source of error with dielectric measurement is anisotropic characteristics of the material. This may be a result of the shape of the sample, the shape of the sample's container, or any anisotropic characteristics the material itself may have.

There are several ways to solve this basic problem. The simplest way is to use a single-feed circularly-polarized antenna. By transmitting and receiving microwave energy that radiates in all orientations, the measurement provides an average of any anisotropic measurements. In this way, the system can reduce error as measurements are repeated.

The second technique is to employ a microstrip resonator where the horizontal polarization and vertical polarization can be excited individually. In this way, the system can directly measure any anisotropic characteristics of the sample being measured. This technique may be extended to a single resonant structure made up of several, individually fed, dipole resonators that share a common center or end point.

Alternatively, this antenna where the individual polarities of the same resonant structure are individually fed from the sensor can be used similar to the single feed antenna. Circular polarization can be achieved with an appropriate microwave feed network that fans the signal from the swept microwave source to each of the feeds of the microwave resonator.

For the antenna mentioned above, the different dipoles oriented in the different directions may also be of different lengths. This increases the dynamic range of the dielectric measurement. Because they have a common center point, they may be used on much smaller samples than the existing multi-resonance antenna. Further, because each dipole is individually fed, there is no ambiguity between the different modes of the different dipoles.

A second source of measurement error can be the effective distance between the microwave resonator and the sample under test. For example, if a flat antenna is used to interrogate a round bottle, the effective coupling to the bottle can vary depending on bottle size and exact shape. By including a small gap of air between the antenna and the sample or the bottle containing the sample there is a reduction in this error. The gap is preferably greater than λ/1000. The air gap can impede the precision of the dielectric measurement, but many applications allow this tradeoff. The preferred method for creating the air-gap is with a thin, dielectric radome, although there are other techniques available.

A final technique for increasing robustness is to make use of the phase information from the return signal. While the resonance point of the antenna can be determined by measuring the minimum return signal as a function of frequency, it may also be measured by looking for the zero phase crossing. These two techniques can combine to form a more robust measurement of the resonance frequency of the antenna with a material under test.

One application of this technology is the identification or verification of materials under test. In the example, where the contents of a bottle of wine with a liquid explosive, a microwave sensor with the above characteristics can be used for screening the contents of bottles to make sure no hazardous materials are present. This procedure is particularly useful for this application as a single antenna can be used to screen bottles of all shapes and sizes. This can be useful in the screening of containers to be loaded onto airplanes, for example.

Another application is an instrument to measure relative dielectric properties. This is useful for measuring mixture ratios of materials with different dielectric constants. It can also be useful for measuring other properties of materials whose change can affect the dielectric constant of the material, for example, temperature.

Another application is process control. Here again, the robustness of the measurements allows for repeatable measurements across a wide variety of conditions. For example, anisotropic materials coming down a slurry pipe can be measured independent of their orientation. Thus mixtures being delivered through plastic pipes or tubes can be measured using the present invention.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 shows a single feed, circularly polarized square patch antenna.

FIG. 2 shows a dual feed patch antenna. One feed excites the horizontal polarization mode of the patch. The other feed excites the vertical polarization excitation of the patch.

FIG. 3 shows a circular patch antenna with diameter D.

FIG. 4a shows a turnstile microstrip antenna. One feed excites the horizontal mode of the resonator, and the other feed excites the vertical mode of the resonator. For this case, the horizontal mode and the vertical mode of the resonator have the same resonant frequency.

FIG. 4b shows a turnstile microstrip antenna. One feed excites the horizontal mode of the resonator, and the other feed excites the vertical mode of the resonator. For this case, the horizontal mode and the vertical mode of the resonator have different resonant frequencies.

FIG. 4c shows a turnstile microstrip antenna. Here there is a single feed that will directly couple to both the horizontal and vertical modes of the resonator at the same time.

FIG. 5 shows the generic single-feed microstrip antenna with a small air-gap and a thin dielectric radome.

FIG. 6 shows in schematic form the circuitry for making dielectric measurements with the aforementioned antennas. For this case, there is a single feed antenna.

FIG. 7 shows in schematic form the basic circuitry for making dielectric measurements with the aforementioned antennas. For this case, there is a multiple feed antenna with the appropriate microstrip feed network.

FIG. 8 shows in schematic form the basic circuitry for making dielectric measurements with the aforementioned antennas. For this case, there is a multiple feed antenna with a feed switch to allow each antenna mode to be driven independently.

### DETAILED DESCRIPTION OF THE INVENTION

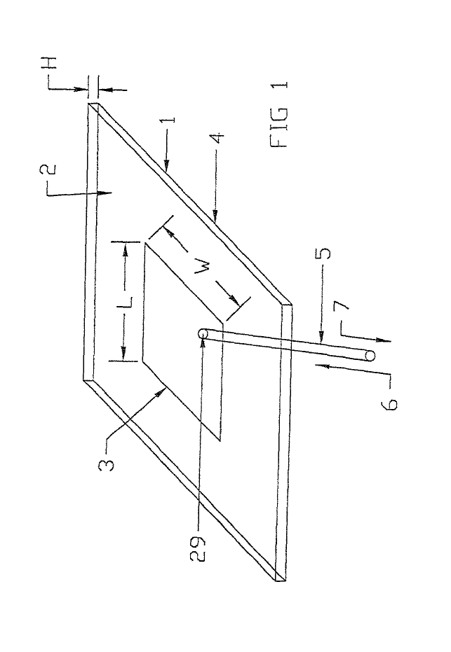

FIG. 1 shows one form of a microstrip resonant sensor (1). It includes a highly conductive ground plane (4), a dielectric substrate (2), and a highly conductive resonant structure on the dielectric substrate (2) opposite the ground plane (4). This embodiment includes a single-feed, circularly polarized, square patch antenna (3). The incident microwave signal (6) is fed through a coaxial cable (5) that is attached to the square patch (3) at the feed point or position (29). The reflected signal (7) is brought back to the sensor by means of an electric feed such as a coaxial cable (5) for measurement. The feed point (29) is selected carefully in order to achieve the desired circular polarization. When placed in the correct location, the single feed point (29) simultaneously excites two resonant modes of the microstrip resonator: horizontal and vertical. When the two modes are excited in this fashion, the antenna is now a circularly polarized antenna.

It is important to make the distinction between the antenna in FIG. 1 and one of similar shape fed to be linearly polarized. Considering only the vertical polarization, the impedance of the feed point to the two vertically polarized resonators is a function of the location between these two points. If the feed point (29) is selected in the center, the impedance is zero and no energy flows to the vertical polarization. The impedance of the vertical polarization becomes a short. It is possible to select a location between the center axis and one of the two outside edges where the impedance matches the feed network. If this is selected for vertical polarization and the short location is selected for the horizontal polarization, there is a well-matched linearly-polarized antenna. However, by choosing a location that is matched to both the vertical polarization and the horizontal polarization of the antenna, this provides circular polarization. This also provides the benefit of exciting both of the resonant modes of the antenna this provides .

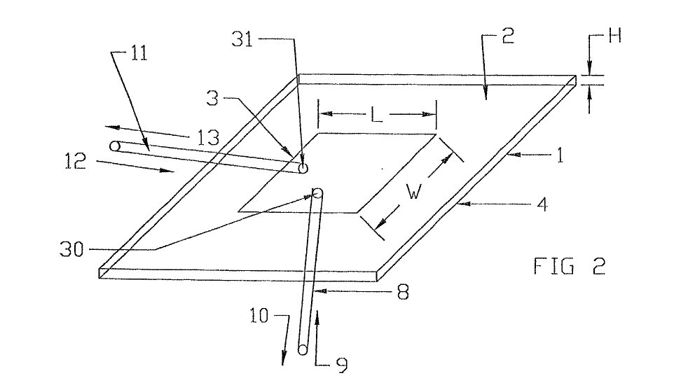

FIG. 2 details the same patch antenna (3) having a length L and width W where both the horizontal and vertical modes of the resonator are excited individually. The horizontal signal (9) is brought to the antenna (3) by means of an electrical feed such as a coaxial cable (8) that is attached at the horizontal feed point (30). The sensor will measure the reflected horizontal signal (10). Similarly, the vertical signal (12) is brought to the antenna (3) by means of a coaxial cable (11) that is attached at the vertical feed point (31). The sensor measures the reflected vertical signal (13). Although the single feed circularly polarized antenna has the advantage of being simpler to manufacture and take measurements from, this dual feed antenna has some advantages over the single feed circularly polarized antenna from FIG. 1. First, allowing excitation of each mode individually allows direct measurement of any anisotropic properties of the sample. This includes anisotropic properties of the sample shape and dielectric constant. Further, as individual measurements can take a few milliseconds each, it is much quicker to measure the horizontal and vertical polarization properties of a material with this technique than with a simple linearly polarized antenna.

The antenna in FIG. 2 can be used in two ways. In the first method, the horizontal and vertical dimensions are the same. This achieves immunity from any anisotropic effects of the sample under test by providing a measurement with the same dielectric response in both the vertical and horizontal direction.

The second method trades off anisotropic immunity for wider dynamic range of dielectric measurement. In practice, the range over which the dielectric constant can be measured is a function of the frequency range of the sensor and the resonant frequency of the antenna in free space. The resonant frequency of the antenna is a function of the length of the antenna. Where λ is the resonant wavelength, the length of the patch antenna is 0.49*λ. Frequency is the speed of light divided by λ. So, the resonant frequency of the patch antenna can be selected by changing the length of its side. For a patch where the vertical and horizontal polarizations are fed individually, one can select different resonant frequencies for the horizontal and vertical modes by selecting appropriate sizes for the width and length. This allows the selection of two different ranges over which one can measure the dielectric constant of the material.

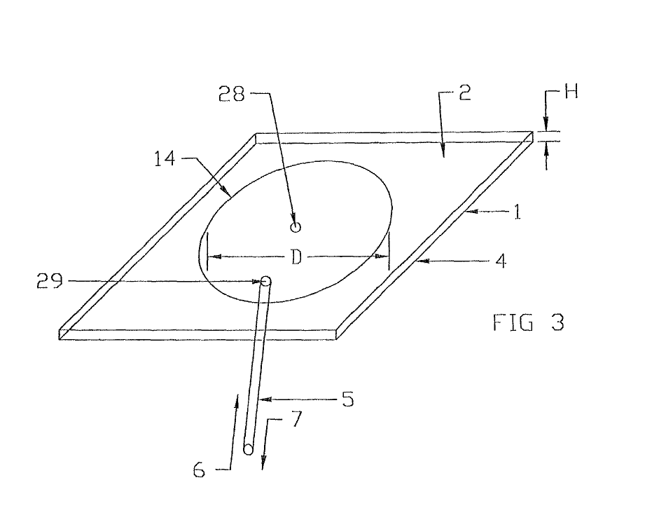

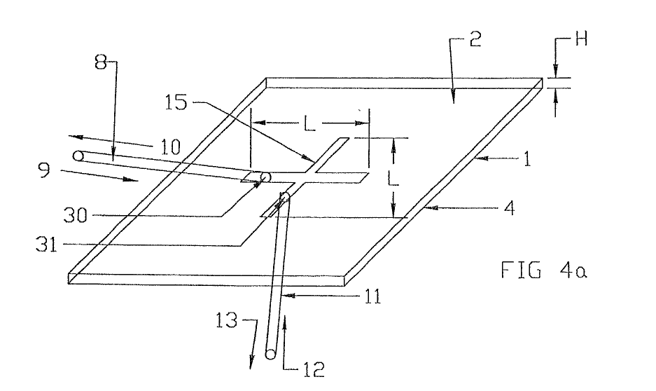

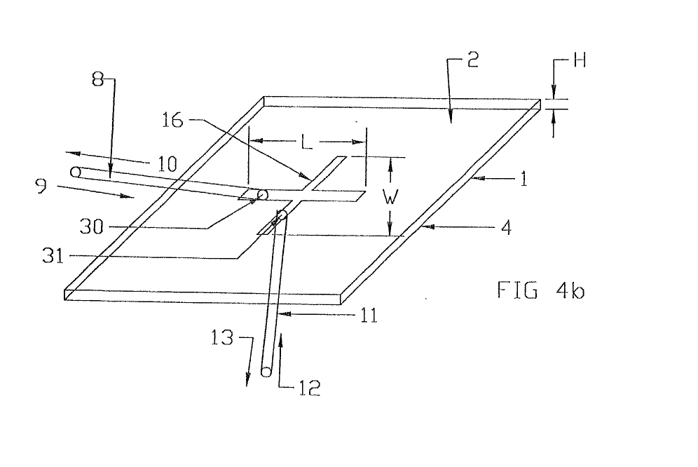

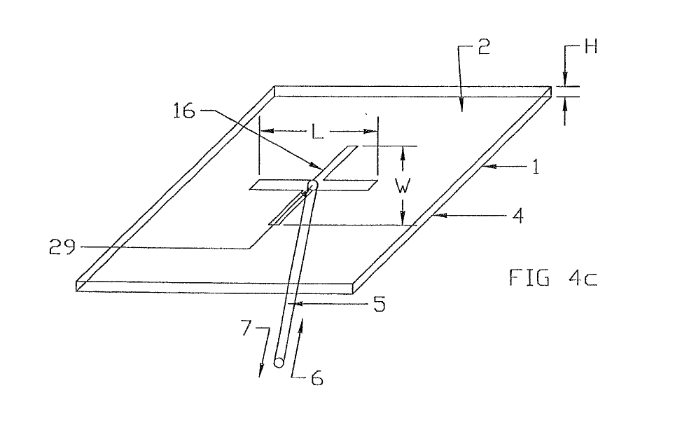

FIG. 3 details a second single feed circularly polarized antenna. Here, the shape of the resonator alone does not give us the circular polarization. This is similar to the antenna in FIG. 1. A single microwave signal from the sensor (6) that travels through an electric feed such as a coaxial cable (5), is attached to the circular antenna 14 of diameter D at the feed point (29). However, the addition of a second feed point (28) that attaches to the ground plane, results in circular polarization. Note that the addition of a second feed point creates the circular polarization. This forces the microwave energy to travel around the antenna FIG. 4a and FIG. 4b detail two embodiments of a turnstile antenna. It is similar to a simple dipole antenna with an important distinction: it is a single microstrip resonator with two independently fed modes of operation. Feeding the vertical mode does not cause the horizontal mode to operate, and feeding the horizontal mode does not cause the vertical mode to operate. This technique can be extended to N dipoles about the center, each with its own feed point to the swept frequency sensor. In this way, multiple linear polarities can be applied to the test material from the same resonant structure by selecting the appropriate feed or by driving the antenna with an appropriate microwave feed network.

FIG. 4a illustrates the case where all dipoles with a common center are of the same length L. This type of turnstile antenna 15 is immune to any anisotropic effects of the sample shape or dielectric constant.

FIG. 4b illustrates the case where the dipoles are not of the same length, but have distinct lengths L and W. Similar to FIG. 4a, the picture illustrates the case where N=2, but the technique can be extended to more resonant modes. Each dipole has its own particular resonance frequency for the test material. While this type of antenna does not have the advantage of anisotropic immunity, it does achieve extended dynamic range for making dielectric measurements. Further, unlike similar structures proposed previously, it achieves extended dynamic range for a smaller sample size.

It is important to note that it is possible to combine the ideas from FIG. 4a and FIG. 4b. For example, an antenna can have 4 dipoles, two of which are designed for one resonant frequency, and two are designed for a second resonant frequency. This idea can of course be extended to more antennas.

The case where the turnstile has two perpendicular dipoles joined at the center, the two dipoles will resonant independent of each other. This is a result of their electric and magnetic fields being perpendicular to each other and will tend not to couple. However, for the case of three or more independent dipoles with a common center, the different dipoles will capacitively couple to each other. This is a constant effect and will not change the basic idea of multiple resonant dipoles in multiple locations with a common center.

FIG. 4c illustrates the same cross shape with a single feed point (29) in the center of the antenna. Here, the single feed point (29) excites both the horizontal and vertical modes of the antenna. The antenna is shown with only two dipoles, however, several can fit about the center point. Similar to other types of antennas, the tradeoff can be made between anisotropic compensation versus dynamic range of the dielectric measurements by selecting appropriate sizes for the length and width of the antenna.

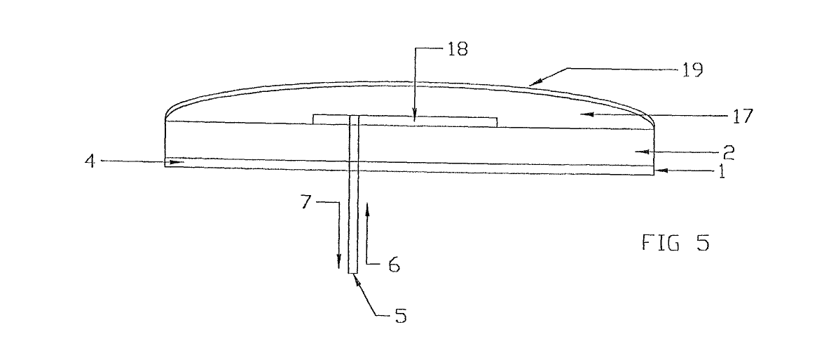

FIG. 5 shows the generic microstrip antenna (18) with an air-gap (17) directly in front of the antenna. The microwave signal (6) travels from the sensor by means of a coaxial cable (5), and the sensor measures the reflected signal (7). This technique is useful for reading the dielectric properties of samples that can not fully be in direct contact with the antenna. Coupling to the material is a complex function of distance from the antenna. Attempting to place non-standard shaped or even small samples in contact with a dielectric resonator shows that the measurements are very sensitive to placement variations. Including a small air gap (17) between the microstrip resonator (18) and the sample can reduce this sensitivity.

It is important to note that for a specific application, the air-gap must be fixed to maintain calibration from measurement to measurement. FIG. 5 illustrates one method of enforcing the air gap: the use of a thin, dielectric radome (19). The radome will allow us to maintain the same air gap between the generic microstrip antenna and any samples under test, although there are many other methods to maintain a constant air gap.

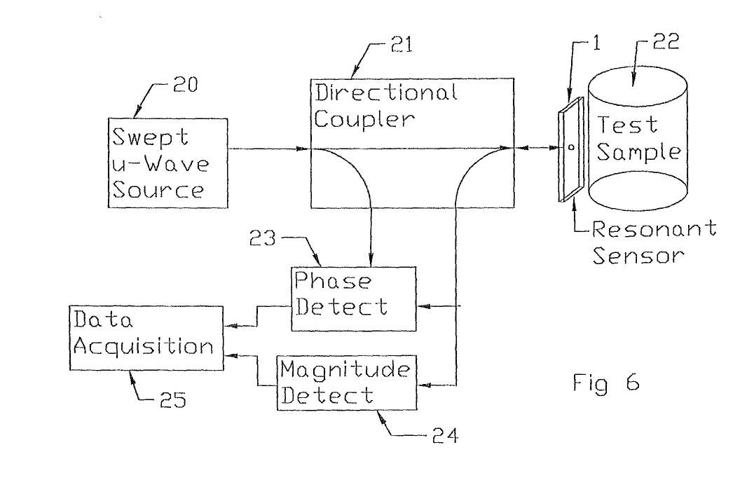

FIG. 6 demonstrates the first of three forms for a complete sensor system. A swept microwave source (20) sends the signal through a directional coupler circuit (21) and into the test sample (22) by means of a resonating antenna (1). The directional coupler circuit (21) accomplishes two things. First, it splits off part of the original swept frequency from the source for phase comparison to the reflected signal. Second, it isolates the reflected from the incident signal to the antenna. This simplifies the process of measuring the reflected wave. The phase and magnitude of the reflected wave are sampled by means of a phase detect circuit (23) and a magnitude detect circuit (24), the outputs of which are stored and processed by the data acquisition module (25). This processing can determine the dielectric properties of the sample under test based on the shape of the magnitude vs. frequency and the phase vs. frequency curves. Magnitude vs. frequency can be used to determine the resonance point for the antenna by looking for the frequency at which the return loss is a minimum. Phase vs. frequency can be used to determine the resonance point for the antenna by looking for the frequency where the phase of the return signal is zero. This particular embodiment is useful for the case where the antenna requires a single feed from the swept microwave source.

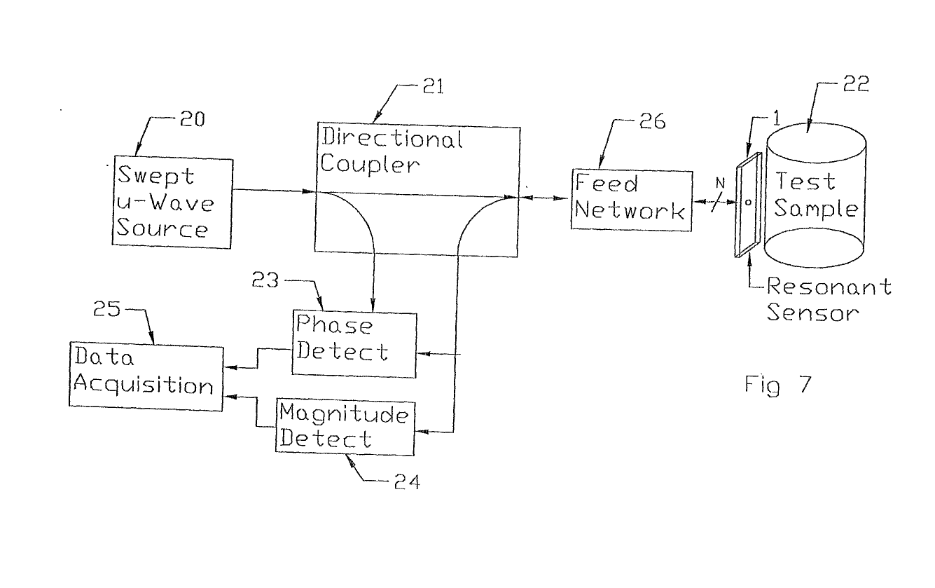

FIG. 7 demonstrates one method for adapting the generic sensor circuit from FIG. 6 to a multi-feed antenna. For the case where it is desirable to achieve a simple polarization from the multi-feed antenna, a microwave feed network (26) is used.

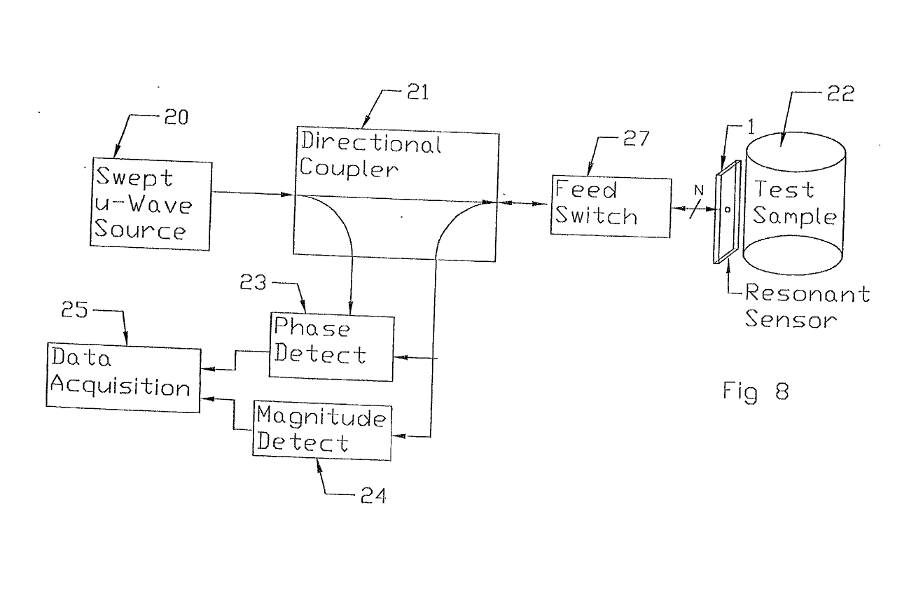

FIG. 8 details one method for making multi-feed measurements where it is preferable to excite each of the different modes of the resonant sensor individually. Here, the simple feed network (26) from FIG. 7 has been replaced by a feed switch (27) which allows the system to choose from among the various individual feeds to the various different resonant modes of the resonant sensor. It is important to note that there are several ways to achieve the same effect of feeding individual modes of the resonant sensor. Multiple directional couplers can be used with the microwave feed switch coming after the reverse coupling. Multiple directional couplers can be used with multiple phase detect and magnitude detect circuitry. This feature allows the system to measure individual modes independently from the others.

These techniques are useful for measuring the dielectric properties of samples within 2.5λ of the antenna. Beyond this distance, the antenna no longer effectively couples to the sample.

In practice, a sensor employs one or more of the different techniques depending on the application. For example, a desktop unit for measuring samples in a lab can use one of the two turnstile antennas trading off anisotropic immunity for dynamic range of the dielectric measurement.

The preceding description is particular to the preferred embodiments and may be changed and modified without substantially changing the nature of the invention. While the invention has been particularly shown and described with reference to preferred embodiments thereof, it will be understood by those skilled in the art that various changes in form and details may be therein without departing from the spirit and scope of the invention as defined by the appended claims.

What is claimed is:

1. A circularly polarized single-feed microstrip resonant sensor for the purpose of measuring a sample dielectric property.

2. The sensor in claim 1 that measures sample dielectric properties with a fixed air gap between the sensor and the sample.

3. The sensor in claim 1 that measure samples dielectric properties within 2.5λ of the sensor.

4. The sensor in claim 1 that measures sample dielectric properties within 2.5λ of the sensor and with a fixed air gap between the sensor and the sample.

5. A single-feed microstrip resonant sensor with multiple modes and multiple polarizations.

6. The senor in claim 5 that measures sample dielectric properties with a fixed air gap between the sensor and the sample.

7. The sensor in claim 5 that measures sample dielectric properties within 2.5λ of the sensor.

8. The sensor in claim 5 that measures sample dielectric properties within 2.5λ of the sensor and with a fixed air gap between the sensor and the sample.

9. A circularly polarized, dual-feed microstrip resonant sensor that measures sample dielectric properties.

10. The sensor in claim 9 that measures sample dielectric properties with a fixed air gap between the sensor and the sample.

11. The sensor in claim 9 that measures sample dielectric properties within 2.5λ of the sensor.

12. The sensor in claim 9 that measures sample dielectric properties within 2.5λ of the antenna and with a small, consistent air gap between the antenna and the sample.

13. A two feed microstrip resonant sensor where one feed excites a horizontal mode of the sensor and the another feed independently excites a vertical mode of the sensor and both modes are at the same resonant frequency.

14. The sensor in claim 13 that measures sample dielectric properties with a fixed air gap between the antenna and the sample.

15. The sensor in claim 13 that measures sample dielectric properties within 2.5λ of the sensor.

16. The sensor in claim 13 that measures sample dielectric properties within 2.5λ of the antenna and with a fixed air gap between the antenna and the sample.

17. A two feed microstrip resonant sensor wherein one feed excites a horizontal mode of sensor and the other feed independently excites the vertical mode of the sensor and both modes are at a different resonant frequency.

18. The sensor in claim 17 that measures sample dielectric properties with a small but fixed air gap between the sensor and the sample.

19. The sensor in claim 17 that measures sample dielectric properties within 2.5λ of the sensor.

20. The sensor in claim 17 that measures sample dielectric properties within 2.5λ of the sensor and with a fixed air gap between the sensor and the sample.

21. A multi-feed (N>2) microstrip resonant sensor wherein the different feeds primarily excite one of the many modes of the resonant sensor and all modes are the same frequency.

22. The sensor in claim 21 that measures sample dielectric properties with a fixed air gap between the sensor and the sample.

23. The sensor in claim 21 that measures sample dielectric properties within 2.5λ of the sensor.

24. The sensor in claim 21 that measures sample dielectric properties within 2.5λ of the sensor and with a fixed air gap between the antenna and the sample.

25. A multi-feed (N>2) microstrip resonant sensor wherein the different feeds primarily excite one of a plurality of modes of the resonant sensor and all modes are at different frequencies.

26. The sensor in claim 25 that measures sample dielectric properties with a fixed air gap between the sensor and the sample.

27. The sensor in claim 25 that measures sample dielectric properties within 2.5λ of the sensor.

28. The sensor in claim 25 that measures sample dielectric properties within 2.5λ of the antenna and with a fixed air gap between the sensor and the sample.

29. A multi-feed (N>2) microstrip resonant sensor wherein the different feeds primarily excite one of many modes of the resonant sensor and some modes share different resonant frequencies.

30. The sensor in claim 29 that measures sample dielectric properties with a fixed air gap between the sensor and the sample.

31. The sensor in claim 29 that measures sample dielectric properties within 2.5λ of the sensor.

32. The sensor in claim 29 that measures sample dielectric properties within 2.5λ of the sensor and with a fixed air gap between the sensor and the sample.

33. The sensor of claim 29 further comprising drive circuitry to detect the individual polarizations to make dielectric measurements.

34. The sensor of claim 29 further comprising a fixed air gap between the resonant dielectric sensor and the sample under test.

35. The sensor of claim 29 further comprising a fixed air gap enforced with a dielectric radome to separate a resonant dielectric sensor from the sample.

36. A method of using phase information to detect a resonance frequency of a resonant dielectric sensor.

37. A method of using a microstrip dielectric resonant sensor to determine bottle contents.

38. A method of using a microstrip dielectric resonant sensor to determine container contents.

39. A method of using a microstrip dielectric resonant sensor to determine mixture ratio of materials in a free-standing container.
